(19) United States
(12) Patent Application Publication
(10) Pub. No.: US 2026/0020377 A1
(43) Pub. Date: Jan. 15, 2026

(54) SEMICONDUCTOR DEVICE

(71) Applicant: EPISTAR CORPORATION, Hsinchu (TW)

(72) Inventors: Wei-Chih Peng, Hsinchu (TW); Yi-Ming Chen, Hsinchu (TW); Chang-Hsiu Wu, Hsinchu (TW); Chih-Yao Chen, Hsinchu (TW); Zhe-Yuan Wu, Hsinchu (TW); Jih-Chien Kao, Hsinchu (TW); Wei-Lun Hsu, Hsinchu (TW)

(21) Appl. No.: 19/265,736

(22) Filed: Jul. 10, 2025

(30) Foreign Application Priority Data
Jul. 10, 2024 (TW) 113125818

(51) Int. Cl. H10F 77/00; H10F 19/40; H10F 71/00; H10F 77/124; H10F 77/42

(52) U.S. Cl. CPC H10F 77/935; H10F 19/40; H10F 77/42; H10F 71/127; H10F 77/124

(57) ABSTRACT

A semiconductor device includes a base, a semiconductor stack, a bonding structure, a contact structure, a conductive structure and a first through hole. The semiconductor stack includes a first semiconductor structure and a second semiconductor structure, and the first semiconductor structure locates between the second semiconductor structure and the base. The bonding structure is disposed between the base and the first semiconductor structure. The contact structure is disposed between the bonding structure and the first semiconductor structure, and is covered the contact structure. The first through hole penetrates the semiconductor stack and the contact structure to contact the conductive structure.

### TECHNICAL FIELD

The present disclosure relates to a semiconductor device, and particularly to a group III-V semiconductor optoelectronic device.

### CROSS REFERENCE TO RELATED APPLICATION

This application claims the right of priority based on TW Application Serial No. 113125818, filed on Jul. 10, 2024, and the content of which is hereby incorporated by reference in its entirety.

### DESCRIPTION OF BACKGROUND ART

Semiconductor devices can be applied to a wide range of applications. Research and development of related materials have been continuously carried out. For example, a group III-V semiconductor material including a group III element and a group V element may be applied to various optoelectronic semiconductor devices, such as light-emitting diodes (LEDs), laser diodes (LDs), photodetectors (PDs), solar cells or power devices (such as switches or rectifiers). These optoelectronic semiconductor devices can be applied in various fields, such as illumination, medical care, display, communication, sensing, or power supply system.

### SUMMARY OF THE DISCLOSURE

The present disclosure provides a semiconductor device, which includes a base, a semiconductor stack, a bonding structure, a contact structure, a conductive structure and a first through hole. The semiconductor stack includes a first semiconductor structure and a second semiconductor structure, and the first semiconductor structure locates between the second semiconductor structure and the base. The bonding structure is disposed between the base and the first semiconductor structure. The contact structure is disposed between the bonding structure and the first semiconductor structure, and is covered the contact structure. The first through hole penetrates the semiconductor stack and the contact structure to contact the conductive structure.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIG. 1A shows a schematic top view of a semiconductor device according to one embodiment of the present disclosure.

FIG. 1B shows a schematic sectional view of the semiconductor device along a section line X-X in FIG. 1A.

FIG. 2A shows a schematic top view of a semiconductor device according to one embodiment of the present disclosure.

FIG. 2B shows a schematic sectional view of the semiconductor device along a section line X-X in FIG. 2A.

FIG. 3 shows a schematic sectional view of the semiconductor device according to one embodiment of the present disclosure.

FIG. 4A shows a schematic top view of a step in a method for manufacturing a semiconductor device of the present disclosure.

FIG. 4B shows a schematic sectional view along a section line A-A in FIG. 4A.

FIG. 4C shows a schematic sectional view along a section line B-B in FIG. 4A.

FIG. 5A shows a schematic top view of a step in the method for manufacturing the semiconductor device of the present disclosure.

FIG. 5B shows a schematic sectional view along the section line A-A in FIG. 5A.

FIG. 6A shows a schematic top view of a step in the method for manufacturing the semiconductor device of the present disclosure.

FIG. 6B shows a schematic sectional view along the section line A-A in FIG. 6A.

FIG. 7A shows a schematic top view of a step in the method for manufacturing the semiconductor device of the present disclosure.

FIG. 7B shows a schematic sectional view along the section line A-A in FIG. 7A.

FIG. 8A shows a schematic bottom view of a step in the method for manufacturing the semiconductor device of the present disclosure.

FIG. 8B shows a schematic sectional view along the section line A-A in FIG. 8A.

FIG. 8C shows a schematic sectional view along the section line B-B in FIG. 8A.

FIG. 9A shows a schematic bottom view of a step in the method for manufacturing the semiconductor device of the present disclosure.

FIG. 9B shows a schematic sectional view along the section line A-A in FIG. 9A.

FIG. 9C shows a schematic sectional view along the section line B-B in FIG. 9A.

FIG. 10A shows a schematic bottom view of a step in the method for manufacturing the semiconductor device of the present disclosure.

FIG. 10B shows a schematic sectional view along the section line A-A in FIG. 10A.

FIG. 10C shows a schematic sectional view along the section line B-B in FIG. 10A.

FIG. 10C′ shows a schematic sectional view along the section line B-B in FIG. 10A according to one embodiment of the present disclosure.

FIG. 11A shows a schematic bottom view of a step in the method for manufacturing the semiconductor device of the present disclosure.

FIG. 11B shows a schematic sectional view along the section line A-A in FIG. 11A.

FIG. 11C shows a schematic sectional view along the section line B-B in FIG. 11A.

FIG. 12A shows a schematic bottom view of a step in the method for manufacturing the semiconductor device of the present disclosure.

FIG. 12B shows a schematic sectional view along the section line A-A in FIG. 12A.

FIG. 12C shows a schematic sectional view along the section line B-B in FIG. 12A.

FIG. 13A shows a schematic bottom view of a step in the method for manufacturing the semiconductor device of the present disclosure.

FIG. 13B shows a schematic sectional view along the section line A-A in FIG. 13A.

FIG. 14A shows a schematic top view of a partial area of a wafer before separation, and FIG. 14B shows a schematic top view of the local area after separation to a semiconductor device according to one embodiment of the present disclosure.

FIG. 15 shows a schematic sectional view of the semiconductor device according to one embodiment of the present disclosure.

### DETAILED DESCRIPTION OF PREFERRED EMBODIMENTS

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

A person skilled in the art can realize that addition of other components based on a structure recited in the following embodiments is allowable. For example, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not physically contact each other. In addition, it should be realized that a positional relationship of a layer/structure may be altered when being observed in different orientations.

A description similar to “a first component/layer/structure is transparent to a light” means that the first component/layer/structure has a transmittance of more than 80% to the light.

Although the invention disclosed herein is described below by specific embodiments, the inventive principles disclosed herein can also be applied to other embodiments.

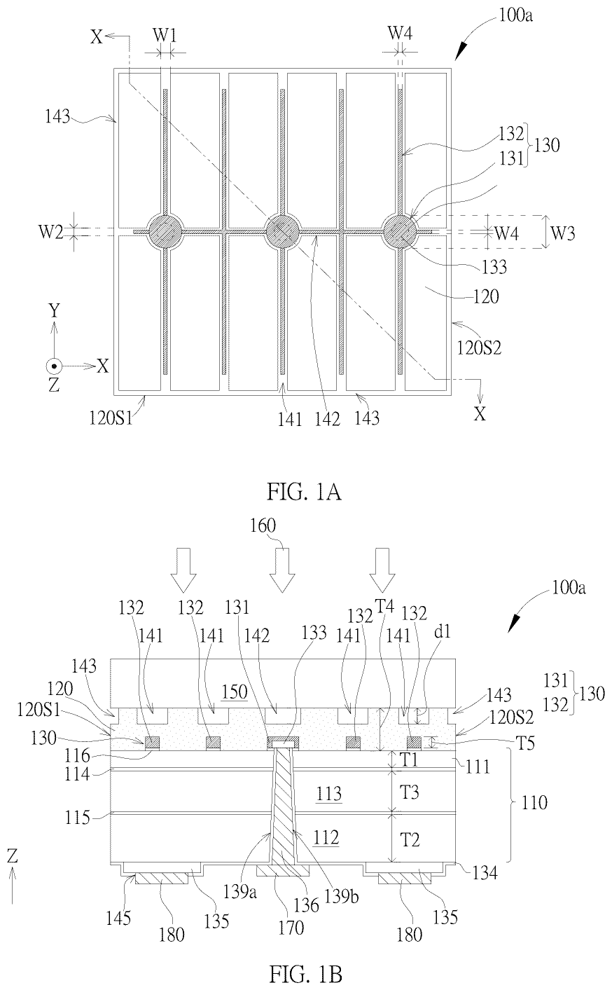

FIG. 1A is a schematic top view of a semiconductor device 100a according to one embodiment of the present disclosure, and FIG. 1B is a schematic sectional view of the semiconductor device 100a along a section line X-X in FIG. 1A. As shown in FIGS. 1A and 1B, the semiconductor device 100a includes a semiconductor stack 110, a base 150, a bonding structure 120, a first electrode structure 170 and a second electrode structure 180. The bonding structure 120 is disposed between the semiconductor stack 110 and the base 150 to bond the semiconductor stack 110 to the base 150. The first electrode structure 170 and the second electrode structure 180 are physically separated from each other and electrically connected to the semiconductor stack 110. The semiconductor device 100a may optionally include a first trench 141 formed in the bonding structure 120. In some embodiments, the first trench 141 is located on a side of the bonding structure 120 adjacent to the base 150.

Referring to FIG. 1A, the bonding structure 120 includes a first side surface 120S1 extending along the X-axis (X direction) and a second side surface 120S2 extending along the Y-axis (Y direction). The first trench 141 extends along a horizontal direction, such as X-axis or Y-axis. For example, in FIG. 1A, the first trench 141 extends along the Y-axis. In some embodiments, the semiconductor device 100a may optionally include a second trench 142 and/or a third trench 143. The first trench 141 and the second trench 142 may be interconnected, and the second trench 142 is not parallel to the first trench 141. As shown in FIG. 1A, the first trench 141 extends toward the first side surface 120S1 along the Y-axis, and the second trench 142 extends toward the second side surface 120S2 along the X-axis. The first trench 141 has a first width W1, and the second trench 142 has a second width W2 which may be larger, smaller or equal to the first width W1. The third trench 143 may be disposed to extend along the first side surface 120S1 and/or the second side surface 120S2 of the bonding structure 120 and connect to the first trench 141 and/or the second trench 142. The number of the first trench 141, the second trench 142 and/or the third trench 143 may be one or multiple.

Referring to FIG. 1B, the semiconductor stack 110 includes a first semiconductor structure 111 and a second semiconductor structure 112. Specifically, the first semiconductor structure 111 is located on the second semiconductor structure 112, the base 150 is disposed on the first semiconductor structure 111, and the bonding structure 120 is disposed between the base 150 and the first semiconductor structure 111. The material compositions of the first semiconductor structure 111 and the second semiconductor structure 112 may be the same or different. In some embodiments, the first semiconductor structure 111 has a first band gap, and the second semiconductor structure 112 has a second band gap smaller than the first band gap. The first semiconductor structure 111 and/or the second semiconductor structure 112 may include a single layer or multiple layers. When the first semiconductor structure 111 (or the second semiconductor structure 112) includes multiple layers, each of the multiple layers may have the same or different materials, and can be lattice-matched. When the multiple layers include different materials and/or band gaps, the first energy gap of the first semiconductor structure 111 (or the second energy gap of the second semiconductor structure 112) can be defined as the smallest band gap among the multiple layers thereof.

The semiconductor device 100a may include a light absorbing device, such as a photovoltaic device or a photo detector. In major embodiments of the present disclosure, the semiconductor device 100a is a photovoltaic element which converts light into electricity, such as a single-junction solar cell or a multi-junction solar cell. In some embodiments, the first semiconductor structure 111 and the second semiconductor structure 112 include a p-type area, an n-type area, and a pn junction. When the first semiconductor structure 111 and/or the second semiconductor structure 112 is a single layer, the p-type area and the n-type area are formed in different regions of the single layer. When the first semiconductor structure 111 and/or the second semiconductor structure 112 includes multiple layers, one of the layers may only include the p-type area and another one of the layers may only include the n-type area. As shown in FIG. 1B, an incident light 160 passes the base 150 and the bonding structure 120 to the semiconductor stack 110, and the first semiconductor structure 111 and the second semiconductor structure 112 absorb the incident light 160 to generate carriers (electrons and holes). More specifically, the first semiconductor structure 111 can absorb portion of the incident light 160 having energy larger than or equal to the first band gap, and the second semiconductor structure 112 can absorb portion of the incident light 160 having energy larger than or equal to the second band gap. As the second band gap is smaller than the first band gap, the second semiconductor structure 112 can absorb the portion of the incident light 160 which has energy smaller than the first band gap and cannot be absorbed by the first semiconductor structure 111, so as to improve the light absorption performance of the semiconductor device 100a. The second semiconductor structure 112 can also absorb the portion of the incident light 160 having energy larger than the first band gap which passes through the first semiconductor structure 111.

In some embodiments, the semiconductor stack 110 may optionally include a third semiconductor structure 113. The third semiconductor structure 113 is disposed between the first semiconductor structure 111 and the second semiconductor structure 112. The third semiconductor structure 113 may include a single layer or multiple layers, and has a structure similar to the first semiconductor structure 111 and/or the second semiconductor structure 112. Similarly, the third semiconductor structure 113 includes the p-type area, the n-type area, and the pn junction. When the third semiconductor structure 113 is a single layer, the p-type area and the n-type area are formed in different regions of the single layer. When the third semiconductor structure 113 includes multiple layers, one of the layers only includes a p-type area and another one of the layers only includes an n-type area. In some embodiments, the third semiconductor structure 113 has a third band gap between the first band gap and the second band gap. Therefore, the third semiconductor structure 113 can enhance absorption to the portion of the incident light 160 having energy smaller than the first band gap and larger than the second band gap, further improving light absorption performance of the semiconductor device 100a. The third semiconductor structure 113 can also absorb the portion of the incident light 160 having energy larger than the first band gap which passes through the first semiconductor structure 111. In some embodiments, the semiconductor stack 110 includes three or more semiconductor structures, and the number of semiconductor structures can be adjusted according to application requirements.

The first semiconductor structure 111 has a first thickness T1, the second semiconductor structure 112 has a second thickness T2, and the third semiconductor structure 113 has a third thickness T3. In some embodiments, the second thickness T2 is larger than the first thickness T1 and the third thickness T3. In some embodiments, the third thickness T3 may be larger than, equal to, or smaller than the second thickness T2.

In some embodiments, the first semiconductor structure 111, the second semiconductor structure 112 and/or the third semiconductor structure 113 may include materials with a band gap of 3.10 eV to absorb light with a wavelength below about 400 nm, or materials with a band gap of 2.14 eV to absorb light with a wavelength below about 580 nm, or materials with a band gap of 1.77 eV to absorb light with a wavelength below about 700 nm, or materials with a band gap of 1.44 eV to absorb light with a wavelength below about 860 nm, or materials with a band gap of 0.66 eV to absorb light with a wavelength below about 1880 nm.

In some embodiments, the semiconductor stack 110 may further include a first tunneling structure 114 disposed between the first semiconductor structure 111 and the second semiconductor structure 112 to help carriers (electrons and/or holes) flow between the first semiconductor structure 111 and the second semiconductor structure 112. In the embodiments that the semiconductor stack 110 includes the third semiconductor structure 113, the semiconductor stack 110 may further include a second tunneling structure 115. As shown in FIG. 1B, the first tunneling structure 114 is disposed between the first semiconductor structure 111 and the third semiconductor structure 113, and the second tunneling structure 115 is disposed between the third semiconductor structure 113 and the second semiconductor structure 112. The first tunneling structure 114 and the second tunneling structure 115 can help carriers flow between the first semiconductor structure 111, the second semiconductor structure 112 and the third semiconductor structure 113 to improve the efficiency of carrier conduction in the semiconductor stack 110. The number of tunneling structures in the semiconductor stack 110 can be adjusted corresponding to the number of semiconductor structures and is not limited to one or two.

In some embodiments, the first semiconductor structure 111, the second semiconductor structure 112, the third semiconductor structure 113, the first tunneling structure 114, and/or the second tunneling structure 115 may include binary, ternary, or quaternary group III-V compound semiconductors, such as AlGaInAs, AlGaInP, AlInGaN, AlAsSb, InGaAsP, InGaAsN, AlGaAsP, GaAs, InGaAs, AlGaAs, AlInAs, GaAsP, GaP, InGaP, AlInP, GaN, InP, InGaN, or AlGaN. In some embodiments, the second semiconductor structure 112 can include a semiconductor of single element, such as germanium (Ge) or silicon (Si). The first semiconductor structure 111, the second semiconductor structure 112, the third semiconductor structure 113, the first tunneling structure 114 and/or the second tunneling structure 115 may include dopant, such as zinc (Zn), beryllium (Be), magnesium (Mg), carbon (C), silicon (Si), germanium (Ge), tin (Sn), sulfur(S), selenium (Se), or tellurium (Te).

The base 150 can be a support substrate for the semiconductor stack 110, and can include insulating material that is transparent to the incident light 160, such as sapphire or glass. The thickness of the base 150 may be in a range of 50 μm and 150 μm to provide enough mechanical strength for the semiconductor device 100a.

The bonding structure 120 is transparent to the incident light 160 and may include a single layer or multiple layers. The bonding structure 120 may include insulating material, such as Su8, benzocyclobutene (BCB), perfluorocyclobutyl (PFCB), epoxy, acrylic resin, cyclo olefin copolymer (COC), PMMA, PET, PC, polyetherimide, fluorocarbon polymer, TaOₓ, Al₂O₃, SiOₓ, TiOₓ, SiNₓ, SiOₓN_{y}, Nb₂O₅ or glass.

In some embodiments, the semiconductor device 100a may optionally include an anti-reflection layer to reduce reflection of the incident light 160. The anti-reflection layer may be disposed between the bonding structure 120 and the semiconductor stack 110, between the bonding structure 120 and the base 150 (not shown), and/or on a side of the base 150 away from the semiconductor stack 110 (not shown).

The first electrode structure 170 and the second electrode structure 180 electrically connect to the first semiconductor structure 111 and the second semiconductor structure 112, respectively, and output the current or voltage generated by the semiconductor stack 110 absorbing the incident light 160 to an external device. Referring to FIGS. 1A and 1B, the semiconductor device 100a may optionally include a conductive structure 130, an electrical connecting element 136, a first through hole 139a and/or an insulating layer 134. As shown in FIG. 1B, the first electrode structure 170 and the second electrode structure 180 may be disposed at a side of the semiconductor stack 110 away from the base 150, that is, disposed below the second semiconductor structure 112. The insulating layer 134 is disposed between the first electrode structure 170 and the second semiconductor structure 112 to prevent the first electrode structure 170 from directly contacting the second semiconductor structure 112 and forming unwanted conductive path. The second semiconductor structure 112 may directly contacts the second electrode structure 180 to form an electrical connection. The is disposed between the first semiconductor structure 111 and the bonding structure 120 and connects the first semiconductor structure 111. The first through hole 139a is formed in the semiconductor stack 110. The electrical connecting element 136 is disposed in the first through hole 139a, and connects the conductive structure 130 to the first electrode structure 170. In other words, the first electrode structure 170 form electrical connection with the first semiconductor structure 111 through the conductive structure 130 and the electrical connecting element 136. According to such arrangement, the first electrode structure 170 and the second electrode structure 180 can be disposed at the same side of the semiconductor stack 110, and the semiconductor device 100a forms a flip-chip type device.

Referring to FIGS. 1A and 1B, the conductive structure 130 includes a connecting portion 131 and an extending portion 132. The number of the connecting portion 131 and/or the extending portion 132 can be one or multiple. In the embodiment of FIG. 1A, the conductive structure 130 includes a plurality of connecting portions 131 arranged in an interval along the X-axis, and a plurality of extending portions 132 extending along the X-axis and/or the Y-axis from the connecting portion 131. Thus, the conductive structure 130 forms a mesh structure to improve the efficiency of carrier collection and the output power. In the horizontal direction (X-axis or Y-axis), the connecting portion 131 has a third width W3 and the extending portion 132 has a fourth width W4. For example, the extending portion 132 parallel to the Y-axis has the fourth width W4 along the X-axis, and the extending portion 132 parallel to the X-axis has the fourth width W4 along the Y-axis. In some embodiments, the fourth width W4 of the extending portion 132 is smaller than the third width W3 of the connecting portion 131. In some embodiments, the fourth width W4 of the extending portion 132 is smaller than or equal to the first width W1 of the first trench 141 and/or the second width W2 of the second trench 142. When the semiconductor device 100a includes the third trench 143, the conductive structure 130 and the third trench 143 may not overlap in the vertical direction (Z-axis).

In the vertical direction (along Z-axis), the position of the first trench 141 and/or the second trench 142 may correspond to the position of the conductive structure 130 to the flatness of the bonding structure 120. As shown in FIG. 1A, the position of the first trench 141 corresponds to the extending portion 132 parallel to the Y-axis, and the position of the second trench 142 corresponds to the extending portion 132 and the connecting portion 131 parallel to the X-axis. The bonding structure 120 has a fourth thickness T4, the conductive structure 130 has a fifth thickness T5, and the first trench 141, the second trench 142 and/or the third trench 143 have a first depth d1. The first trench 141, the second trench 142 and the third trench 143 may have the same or different depths. When the first trench 141, the second trench 142 and the third trench 143 have different depths, the first depth d1 refers to the largest depth thereof. In some embodiments, the first depth d1 is smaller than the fourth thickness T4, and the sum of the first depth d1 and the fifth thickness T5 is smaller than the fourth thickness T4. In some embodiments, the fourth thickness T4 of the bonding structure 120 may be between 1 μm and 3 μm, and the first depth d1 may be between 0.05 μm and 0.3 μm.

As shown in FIG. 1B, a first through hole 139a is formed in the semiconductor stack 110 and extends along the vertical direction (Z-axis), and penetrates the semiconductor stack 110. In the vertical direction, the position of the first through hole 139a corresponds to the position of the connecting portion 131. The electrical connecting element 136 is disposed in the first through hole 139a and extends along the vertical direction to connect the connecting portion 131 of the conductive structure 130 and the first electrode structure 170. The insulating layer 134 is disposed beneath the second semiconductor structure 112 and in the first through hole 139a to prevent the first electrode structure 170 from directly contacting the second semiconductor structure 112 and to prevent the electrical connecting element 136 from directly contacting the semiconductor stack 110. More specifically, the insulating layer 134 in the first through hole 139a surroundings the electrical connecting element 136. The semiconductor device 100a optionally includes a second through hole 139b which is formed in the insulating layer 134 and corresponds to the connecting portion 131 in the vertical direction, and the electrical connecting element 136 is disposed in the second through hole 139b without directly contacting the semiconductor stack 110. In some embodiments, the width of the second through hole 139b is smaller than that of the first through hole 139a, and the width of the electrical connecting element 136 is substantially the same as that of the second through hole 139b. The number of the first through hole 139a, the second through hole 139b and/or the electrical connecting element 136 in the semiconductor device 100a can be one or multiple. The number of the first through hole 139a, the second through hole 139b and/or the electrical connecting element 136 may correspond to the number of the connecting portions 131. In some embodiments, the insulating layer 134 may further be disposed between the second semiconductor structure 112 and the second electrode structure 180, and may include a contact opening 145 for the second electrode structure 180 to contact the second semiconductor structure 112. The number of the contact openings 145 can be one or multiple. In the vertical direction, the contact opening 145 does not overlap with the connecting portion 131.

In some embodiments, the first electrode structure 170 may be disposed corresponding to the position of the connecting portion 131, i.e., the first electrode structure 170 overlaps with the connecting portion 131 in the vertical direction. The second electrode structure 180 does not overlap with the connecting portion 131 in the vertical direction. The number of the first electrode structure 170 and/or the second electrode structure 180 may be one or multiple, and the number of the first electrode structures 170 and the number of the second electrode structures 180 may be the same or different. The number of the first electrode structures 170 may correspond to the number of the connecting portions 131. The number of the second electrode structures 180 may correspond to the number of the contact opening 145 of the insulating layer 134.

The first electrode structure 170 and/or the second electrode structure 180 may include a single layer or multiple layers. The first electrode structure 170, the second electrode structure 180, the conductive structure 130, and/or the electrical connecting element 136 may include a metal material, such as aluminum (Al), chromium (Cr), copper (Cu), tin (Sn), gold (Au), nickel (Ni), titanium (Ti), platinum (Pt), lead (Pb), zinc (Zn), cadmium (Cd), antimony (Sb), cobalt (Co), beryllium (Be), germanium (Ge) or alloys containing two or more of above metals.

The insulating layer 134 may include insulating material, such as tantalum oxide (TaOₓ), aluminum oxide (AlOₓ), silicon oxide (SiOₓ), titanium oxide (TiOₓ), silicon nitride (SiNₓ), silicon oxynitride (SiOₓN_{y}), niobium pentoxide (Nb₂O₅) or spin-on glass (SOG). The insulating layer 134 may include a single layer or multiple sublayers. When the insulating layer 134 includes multiple sublayers, each of the sublayers may include the same or different insulating materials.

The semiconductor device 100a may optionally include a protecting layer 133 located between the connecting portion 131 and the first through hole 139a. As shown in FIGS. 1A and 1B, in the vertical direction, the protecting layer 133 is disposed at a position corresponding to the first through hole 139a. In some embodiments, the protecting layer 133 has a width larger than that of the first through hole 139a, so that the protecting layer 133 completely covers the first through hole 139a to prevent damage to the connecting portion 131 during forming the first through hole 139a. In some embodiments, the width of the protecting layer 133 is smaller than the third width W3 of the connecting portion 131, and the protecting layer 133 is covered by the connecting portion 131. When the semiconductor device 100a includes the protecting layer 133, the second through hole 139b may optionally penetrate the protecting layer 133, and the electrical connecting element 136 may connect the protecting layer 133 or the connecting portion 131 directly.

The material of the protecting layer 133 may include metal or insulating material. The metal may include gold (Au), platinum (Pt) or titanium (Ti), or an alloy of any two or more of the above metals. The insulating material may include tantalum oxide (TaOₓ), aluminum oxide (AlOₓ), silicon oxide (SiOₓ), titanium oxide (TiOₓ), silicon nitride (SiNₓ), silicon oxynitride (SiOₓN_{y}), niobium pentoxide (Nb₂O₅) or spin-on glass (SOG).

The semiconductor device 100a may further optionally include a first contact structure 116 and/or a second contact structure 135. As shown in FIG. 1B, the first contact structure 116 is disposed between the and the first semiconductor structure 111. The first contact structure 116 may form an ohmic contact with the conductive structure 130 to reduce the resistance between the conductive structure 130 and the first semiconductor structure 111. The first contact structure 116 may include a single layer or multiple layers. The first contact structure 116 may be patterned to prevent the incident light 160 from being absorbed by the first contact structure 116 and reducing the photoelectric conversion efficiency of the semiconductor device 100a. The pattern of the first contact structure 116 may correspond to part or all of the conductive structure 130. For example, the first contact structure 116 may be disposed below the connecting portion 131 and the extending portion 132, or only below the extending portion 132. The first through hole 139a, the second through hole 139b and/or the electrical connecting element 136 penetrate the first contact structure 116 to connect the connecting portion 131 (or the protecting layer 133). In some embodiments, in the horizontal direction (X-axis or Y-axis), the width of the first contact structure 116 may be equal to or smaller than the width of the extending portion 132. In some embodiments, the thickness of the first contact structure 116 may be between 0.4 μm and 0.6 μm.

The second contact structure 135 is disposed between the second electrode structure 180 and the second semiconductor structure 112 to reduce the resistance between the second semiconductor structure 112 and the second electrode structure 180, thus the operating voltage of the semiconductor device 100a can be further reduced. The second contact structure 135 can include a single layer or multiple layers, and the second contact structure 135 can be patterned to corresponding to the second electrode structure 180.

The first contact structure 116 and/or the second contact structure 135 can include the aforementioned binary, ternary or quaternary group III-V compound semiconductor or metal, such as GaAs, InGaAs, GaP, Ti or Pd.

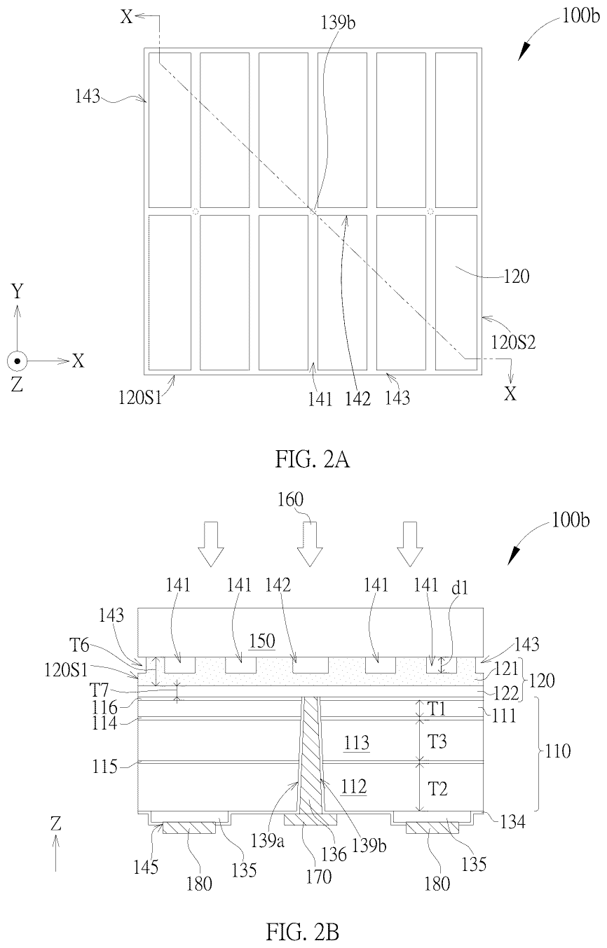

FIG. 2A is a top view of a semiconductor device 100b according to one embodiment of the present disclosure, and FIG. 2B is a schematic sectional view of the semiconductor device 100b along section line X-X shown in FIG. 2A. The semiconductor device 100b has a similar structure to the aforementioned semiconductor device 100a, and the semiconductor device 100b does not include the conductive structure 130 and the bonding structure 120 thereof includes multiple layers. Referring to FIGS. 2A and 2B, the bonding structure 120 of the semiconductor device 100b includes a first bonding layer 121 and a second bonding layer 122. The second bonding layer 122 is located between the first bonding layer 121 and the semiconductor stack 110, and electrically connect the first semiconductor structure 111 and the electrical connecting element 136. More specifically, the first bonding layer 121 includes the aforementioned insulating material, and the second bonding layer 122 includes transparent conductive material. As such, carriers generated by light absorption of the first semiconductor structure 111 can be collected by the second bonding layer 122, and then be conducted to the first electrode structure 170 via the electrical connecting element 136. The transparent conductive material of the second bonding layer 122 may include transparent metal oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium cerium oxide (ICO), indium tungsten oxide (IWO), indium titanium oxide (ITiO), zinc oxide (ZnO), indium zinc oxide (IZO), indium gallium oxide (IGO) or gallium aluminum zinc oxide (GAZO). In some embodiments, the first contact structure 116 can be optionally disposed between the second bonding layer 122 and the first semiconductor structure 111 to reduce the resistance between the second bonding layer 122 and the first semiconductor structure 111.

As shown in FIG. 2A, the arrangements of the first trench 141, the second trench 142 and/or the third trench 143 in the semiconductor device 100b are the same as those in FIG. 1A. In the semiconductor device 100b, the first trench 141, the second trench 142 and the third trench 143 are disposed in the first bonding layer 121 without connecting the second bonding layer 122. As shown in FIG. 2B, the first bonding layer 121 has a sixth thickness T6, and the second bonding layer 122 has a seventh thickness T7 which is equal to or smaller than the sixth thickness T6. In this embodiment, the first depth d1 of the first trench 141, the second trench 142 and/or the third trench 143 are smaller than the sixth thickness T6 of the first bonding layer 121. The sum of the sixth thickness T6 and the seventh thickness T7 may be in a range of 1 μm to 2 μm. The positions, relative relationships, material compositions, and other contents of other structure/layer/element of the semiconductor device 100b have been described in detail in the previous embodiments and will not be repeated herein.

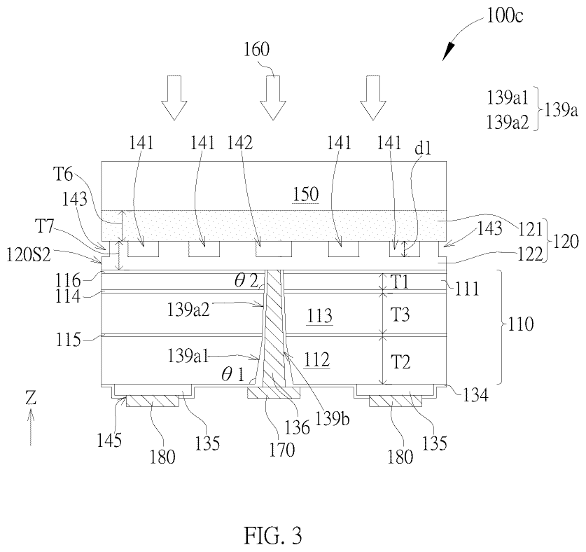

FIG. 3 is a schematic sectional view of a semiconductor device 100c according to one embodiment of the present disclosure. The semiconductor device 100c in FIG. 3 has a similar structure to the aforementioned semiconductor device 100b in FIG. 2B. The main difference is that the first trench 141, the second trench 142 and/or the third trench 143 of the semiconductor device 100c are disposed in the second bonding layer 122 instead of in the first bonding layer 121. In this embodiment, the first depth d1 of the first trench 141, the second trench 142 and/or the third trench 143 are smaller than the seventh thickness T7 of the second bonding layer 122.

The first through hole 139a may include several zones having different inclination angles (slopes). Referring to FIG. 3, the first through hole 139a of the semiconductor device 100c has a first zone 139al and a second zone 139a2 connected the first zone 139a1. The first zone 139al is formed in the second semiconductor structure 112. The second zone 139a2 is formed in the first contact structure 116, the first semiconductor structure 111, the first tunneling structure 114, the third semiconductor structure 113, and the second tunneling structure 115, and may further formed in the second semiconductor structure 112. The first zone 139al and the surface of the second semiconductor structure 112 has a first inclination angle θ1 formed therebetween, and the second zone 139a2 and the surface of the first semiconductor structure 111 has a second inclination angle θ2 formed therebetween. In some embodiments, the second inclination angle θ2 is smaller than the first inclination angle θ1. The second through hole 139b may have only one inclination angle (shown in FIG. 3), or may be formed in a shape substantially the same as the first through hole 139a and have two inclination angles (not shown). The first through hole 139a and/or the second through hole 139b with two inclined angles can also be applied to other embodiments of the present disclosure. The positions, relative relationships, material compositions, and other contents of other structure/layer/element of the semiconductor device 100c have been described in detail in the previous embodiments and will not be repeated herein.

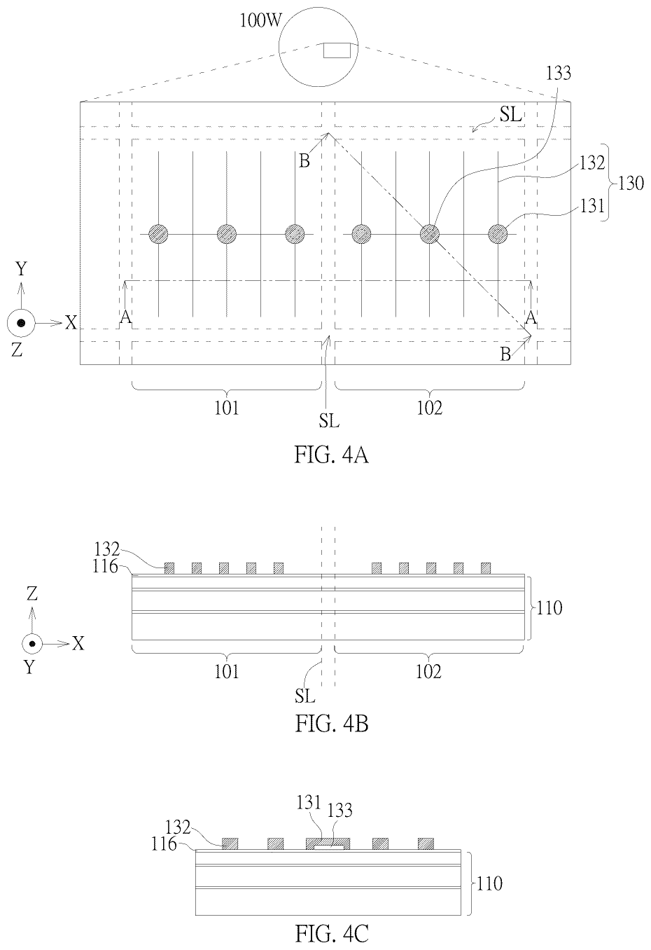

FIGS. 4 to 13 illustrate a method of manufacturing the semiconductor device 100a according to one embodiment of the present disclosure. Referring to FIGS. 4A to 4C, FIG. 4A is a partial top view of a framed area of a wafer 100W, FIG. 4B is a sectional view along a section line A-A in FIG. 4A, and FIG. 4C is a sectional view along the section line B-B in FIG. 4A. First, the wafer 100W including a semiconductor stack 110 is provided, and then a first chip region 101, a second chip region 102, and scribe lines SL surrounding the first chip region 101 and the second chip region 102 are defined on the wafer 100W.

Then, the first contact structure 116, the protecting layer 133, and the conductive structure 130 are sequentially formed on the wafer 100W. The first contact structure 116 can be formed on the semiconductor stack 110 through a deposition process and can be pattered. The protecting layer 133 can be formed on the first contact structure 116 through a patterning process and a deposition process, and the conductive structure 130 can be formed on the first contact structure 116 and the protecting layer 133 through a patterning process and a deposition process. The patterning of the first contact structure 116 can be performed directly after the deposition process, or after the conductive structure 130 is formed. The conductive structure 130 includes the connecting portion 131 and the extending portion 132. The position of the connecting portion 131 corresponds to the position of the protecting layer 133, so that the connecting portion 131 covers the protecting layer 133.

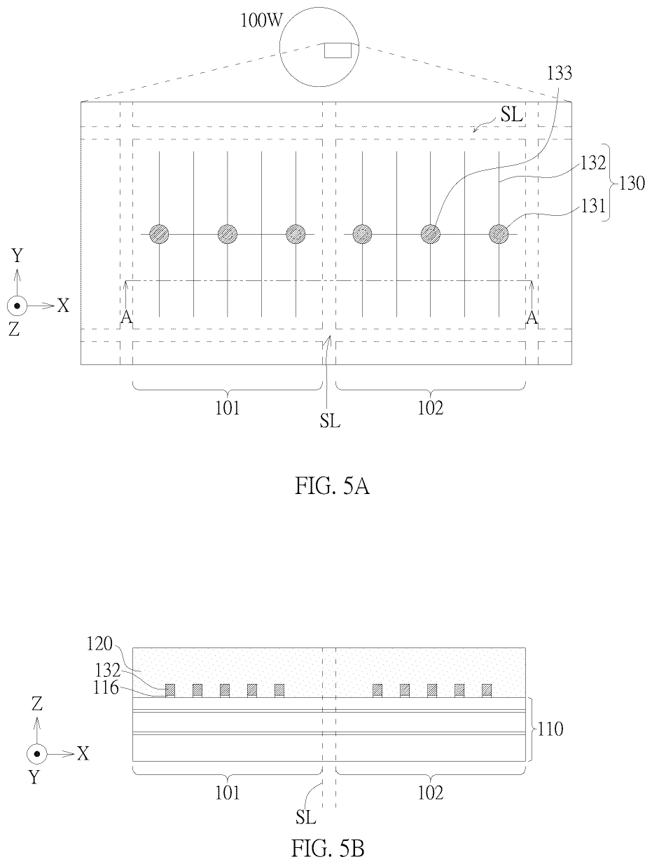

Referring to FIGS. 5A to 5B for a next step of the method of manufacturing the semiconductor device 100a. FIG. 5A is the partial top view of the wafer 100W, and FIG. 5B is a sectional view along the section line A-A in FIG. 5A. In this step, by using the conductive structure 130 as a mask, the first contact structure 116 is etched and patterned. Then, the bonding structure 120 is formed on the semiconductor stack 110 and the conductive structure 130 by a deposition process. The bonding structure 120 covers the conductive structure 130 and the patterned first contact structure 116 and connects the first semiconductor structure 111.

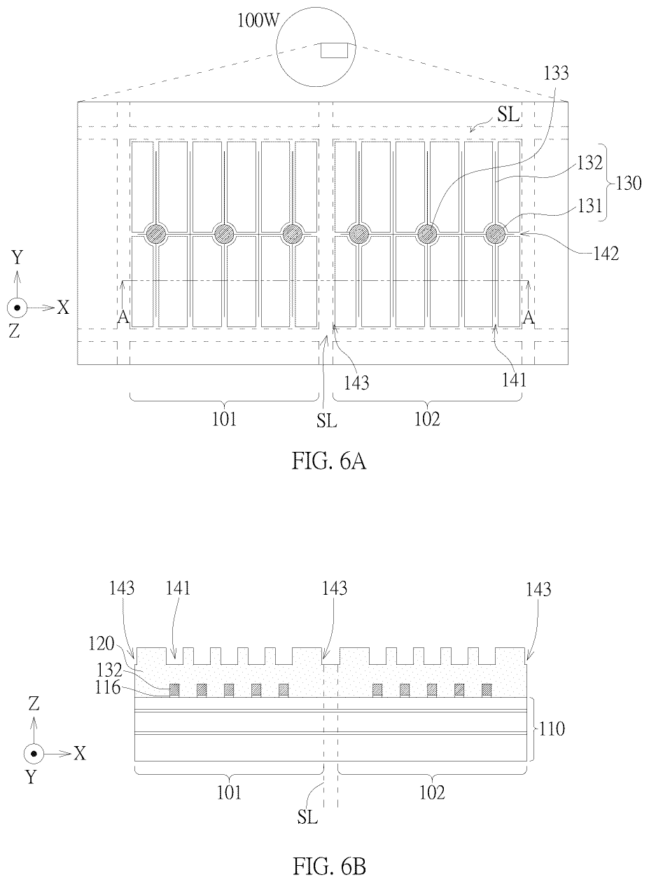

Referring to FIGS. 6A to 6B for a next step of the method of manufacturing the semiconductor device 100a. FIG. 6A is the partial top view of the wafer 100W, and FIG. 6B is a sectional view along the section line A-A in FIG. 6A. In this step, by using a patterned mask (not shown, such as a patterned photoresist layer) and performing an etching process, a first trench 141, a second trench 142, and a third trench 143 are formed on a side of the bonding structure 120 away from the semiconductor stack 110. In the embodiment of FIG. 6A, the first trench 141 corresponds to the extending portion 132 parallel to the Y-axis, and the second trench 142 corresponds to the extending portion 132 parallel to the X-axis. The third trench 143 corresponds to the scribe lines SL and the edge of the first chip region 101 and/or the second chip region 102. The first trench 141 and the second trench 142 may be interconnected, and the third trench 143 may connect to the first trench 141 and/or the second trench 142.

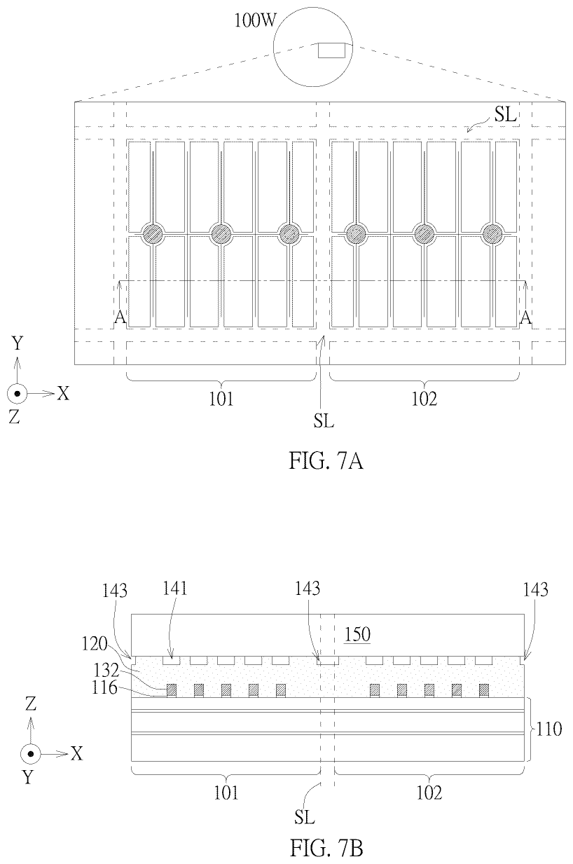

Referring to FIGS. 7A to 7B for a next step of the method of manufacturing the semiconductor device 100a. FIG. 7A is the partial top view of the wafer 100W, and FIG. 7B is a sectional view along the section line A-A in FIG. 7A. In this step, the base 150 is provided and a bonding process is performed to bond the base 150 to the bonding structure 120, so that the base 150 covers the first trench 141, the second trench 142 and the third trench 143. During the bonding process, there is air between the base 150 and the bonding structure 120, and the air may form bubbles at the interface between the base 150 and the bonding structure 120, thereby reducing the bonding strength. In the present disclosure, during the bonding process, the air can be discharged through the first trench 141, the second trench 142 and/or the third trench 143 to avoid the occurrence of bubbles, thereby improving the reliability and production yield of the semiconductor device 100a. Before the bonding process, a planarization process may be optionally performed on the side of the bonding structure 120 away from the semiconductor stack 110 to improve the surface flatness and bonding strength. During the planarization process, a portion of the bonding structure 120 is removed, so that the thickness of the bonding structure 120 is reduced. Thus, the depth of the first trench 141, the second trench 142 and the third trench 143 in FIG. 7B is less than the depth of the first trench 141, the second trench 142 and the third trench 143 in FIG. 6B.

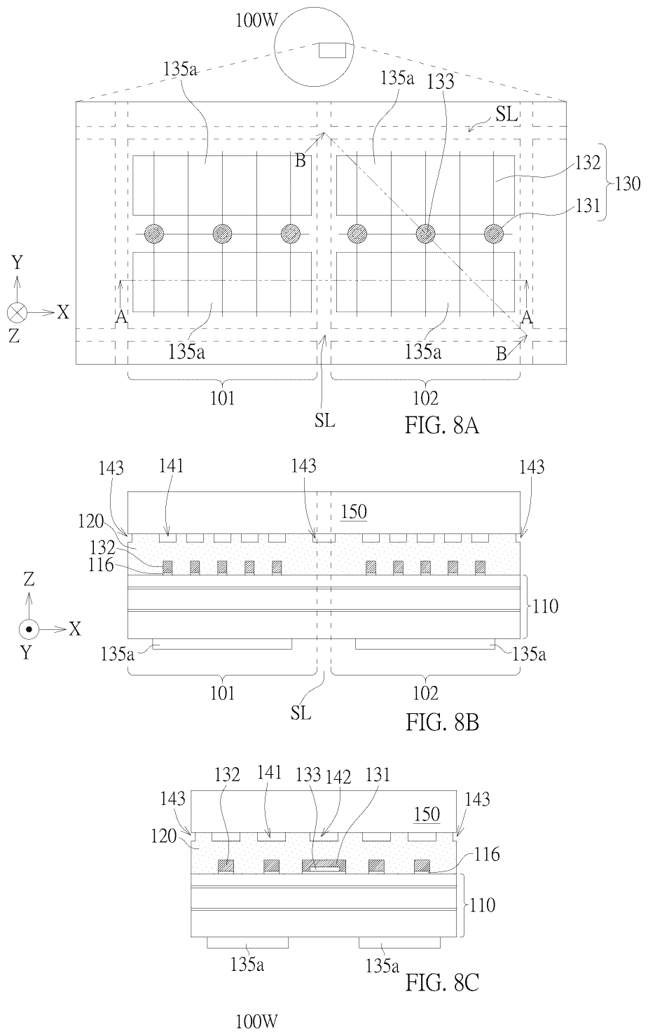

In the following steps shown in FIGS. 8 to 13, the wafer 100W can be optionally flipped upside down for performing subsequent process. To make the drawings consistent, FIGS. 8 to 13 are drawn in a manner that the wafer 100W is not flipped.

Referring to FIGS. 8A to 8C for a next step of the method of manufacturing the semiconductor device 100a. FIG. 8A is a partial bottom view of the wafer 100W; FIG. 8B is a sectional view along the section line A-A in FIG. 8A, and FIG. 8C is a sectional view along the section line B-B in FIG. 8A. In this step, the second contact structure 135 is formed below the semiconductor stack 110 through a deposition process and a patterning process, and the second contact structure 135 is in direct contact with the bottom surface of the second semiconductor structure 112. In some embodiments, the second contact structure 135 includes a plurality of contact portions 135a which are separated from each other and located below the first chip region 101 and/or the second chip region 102. There are one or more contact portions 135a located below each of the first chip region 101 and the second chip region 102, and each of the contact portions 135a does not overlap with the connecting portion 131 in the vertical direction. For example, as shown in FIG. 8A, there are two contact portions 135a located below the second semiconductor structure 112 in the first chip region 101 (or the second chip region 102), and the two contact portions 135a extends along the X-axis.

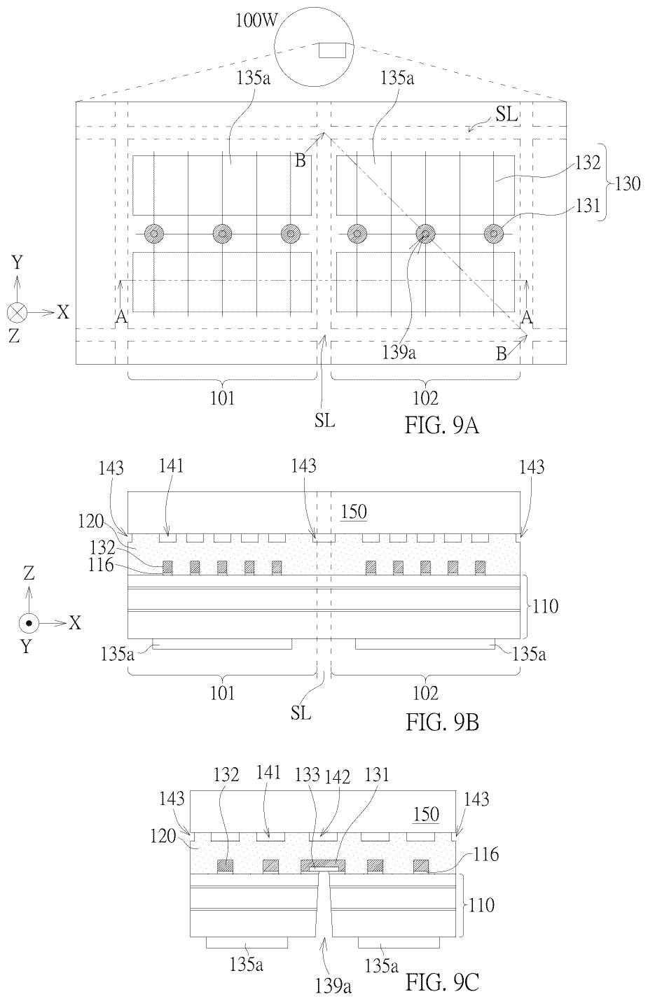

Referring to FIGS. 9A to 9C for a next step of the method of manufacturing the semiconductor device 100a. FIG. 9A is a partial bottom view of the wafer 100W; FIG. 9B is a sectional view along the section line A-A in FIG. 9A, and FIG. 9C is a sectional view along the section line B-B in FIG. 9A. In this step, a first through hole 139a is formed in the semiconductor stack 110 through an etching process. The position of the first through hole 139a corresponds to the protecting layer 133 (or the connecting portion 131). In other words, the first through hole 139a and the contact portion 135a do not overlap in the vertical direction. The number of the first through holes 139a may the same as the number of the connecting portions 131. For example, as shown in FIG. 9A, the number of the connecting portion 131 and the number of the first through hole 139a in the first chip region 101 (or the second chip region 102) are both three.

As shown in FIG. 9A, the first through hole 139a may have a tapered profile. In such case, the width of the first through hole 139a is defined as the width of the side close to the connecting portion 131. In some embodiments, the width of the first through hole 139a is smaller than that of the protecting layer 133, so that the first through hole 139a only exposes the protecting layer 133 but does not expose the connecting portion 131. More specifically, the etching medium (e.g., plasma) applied in the etching process of forming the first through hole 139a may be corrosive to the connecting portion 131, and byproducts formed by etching the connecting portion 131 may remain in the first through hole 139a to increase the risk of current leakage. By providing the protecting layer 133 between the connecting portion 131 and the semiconductor stack 110, the etching medium can be blocked to prevent corrosion of the connecting portion 131, thereby increasing the production yield of the semiconductor device 100a. In some embodiments, the first through hole 139a can be formed by two or more etching processes, so that the first through hole 139a may have the first inclination angle θ1 and the second inclination angle θ2 as shown in FIG. 3.

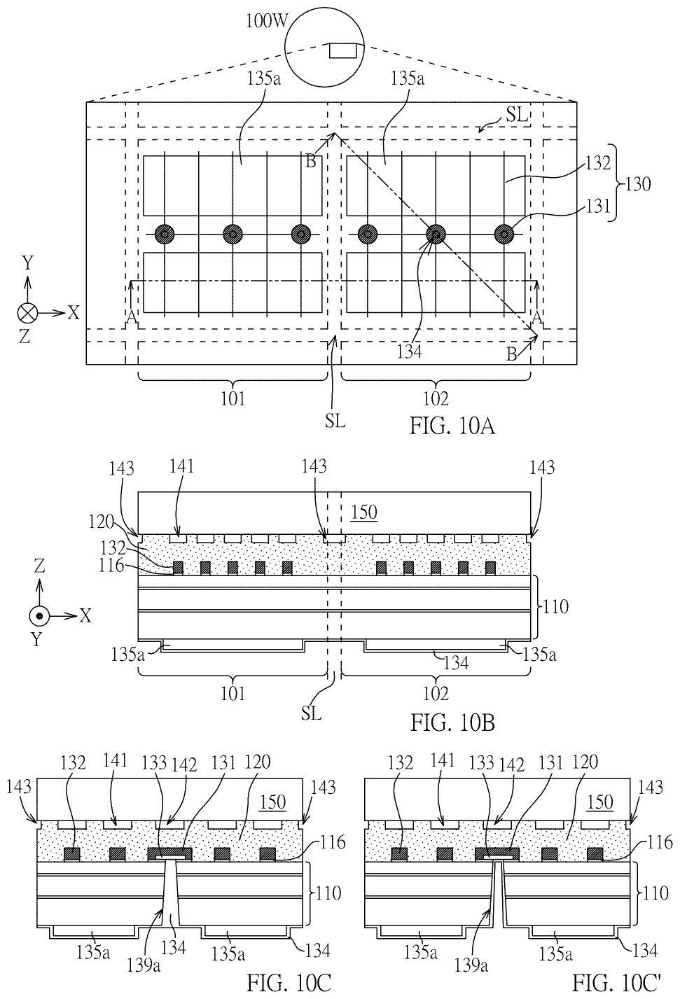

Referring to FIGS. 10A to 10C for a next step of the method of manufacturing the semiconductor device 100a. FIG. 10A is a partial bottom view of the wafer 100W; FIG. 10B is a sectional view along the section line A-A in FIG. 10A, FIG. 10C is a sectional view along the section line B-B in FIG. 10A, and FIG. 10C′ is a sectional view along the section line B-B in FIG. 10A according to one embodiment of the present disclosure. In this step, the insulating layer 134 is conformally formed below the semiconductor stack 110 and the second contact structure 135 through a deposition process, and may conformally cover the surface of the second semiconductor structure 112 and the surface of the second contact structure 135. The insulating layer 134 may further be formed in the first through hole 139a to cover the sidewall of the first through hole 139a and the protecting layer 133 (or the connecting portion 131). More specifically, the insulating layer 134 may completely fill the first through hole 139a (as shown in FIG. 10C) or partially fill the first through hole 139a (as shown in FIG. 10C). In some embodiments, the insulating layer 134 may cover or conformally cover the sidewall of the first through hole 139a and the protecting layer 133 (as shown in FIG. 10C′). Further details regarding the insulating layer 134 may be referred to in the foregoing paragraphs and will not be reiterated herein.

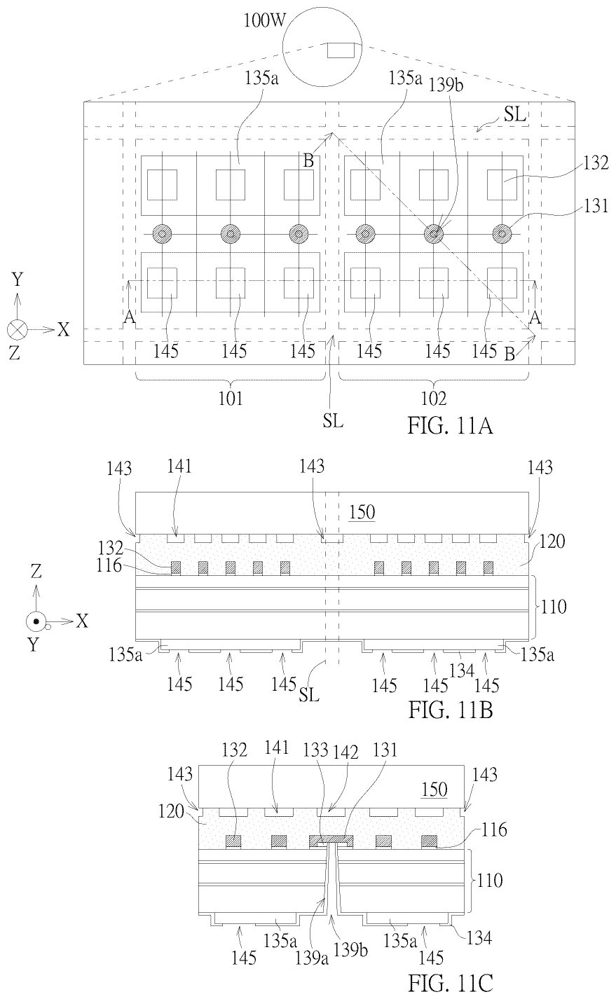

Referring to FIGS. 11A to 11C for a next step of the method of manufacturing the semiconductor device 100a. FIG. 11A is a partial bottom view of the wafer 100W; FIG. 11B is a sectional view along the section line A-A in FIG. 11A, and FIG. 11C is a sectional view along the section line B-B in FIG. 11A. In this step, the contact opening 145 and the second through hole 139b are formed in the insulating layer 134 through a patterning process and an etching process to expose the second contact structure 135 and the protecting layer 133 (or the connecting portion 131), respectively. More specifically, the second through hole 139b is formed in a part of the insulating layer 134 which locates in the first through hole 139a and corresponds to the protecting layer 133, and can optionally penetrate the protecting layer 133 to expose the connecting portion 131. The second through hole 139b can also have a tapered profile, and the width of the second through hole 139b is defined as the width of the side close to the connecting portion 131. In some embodiments, the width of the second through hole 139b is smaller than the width of the protecting layer 133 and the width of the first through hole 139a. The number of contact openings 145 can be one or multiple, in order to expose one or multiple portions of the second contact structure 135 (or the contact portion 135a).

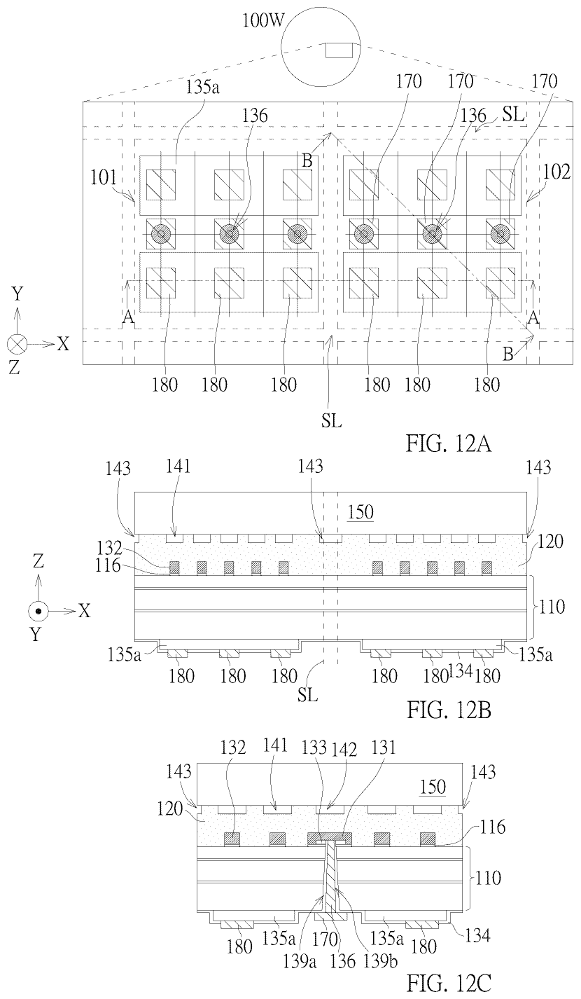

Referring to FIGS. 12A to 12C for a next step of the method of manufacturing the semiconductor device 100a. FIG. 12A is a partial bottom view of the wafer 100W; FIG. 12B is a sectional view along the section line A-A in FIG. 12A, and FIG. 12C is a sectional view along the section line B-B in FIG. 12A. In this step, through deposition and patterning processes, the electrical connecting element 136, the first electrode structure 170 and the second electrode structure 180 are formed. The electrical connecting element 136 is formed within the second through hole 139b, extends in a vertical direction to connect to the connecting portion 131, and is separated from the semiconductor stack 110 by the insulating layer 134. The first electrode structure 170 is disposed corresponding to the position of the connecting portion 131. The second electrode structure 180 is formed within the contact opening 145 and is in direct contact with the second contact structure 135. In some embodiments, the first electrode structures 170 and the second electrode structures 180 can be provided in plural, and the plurality of first electrode structures 170 and the plurality of second electrode structures 180 can be arranged in an array, as shown in FIG. 12A.

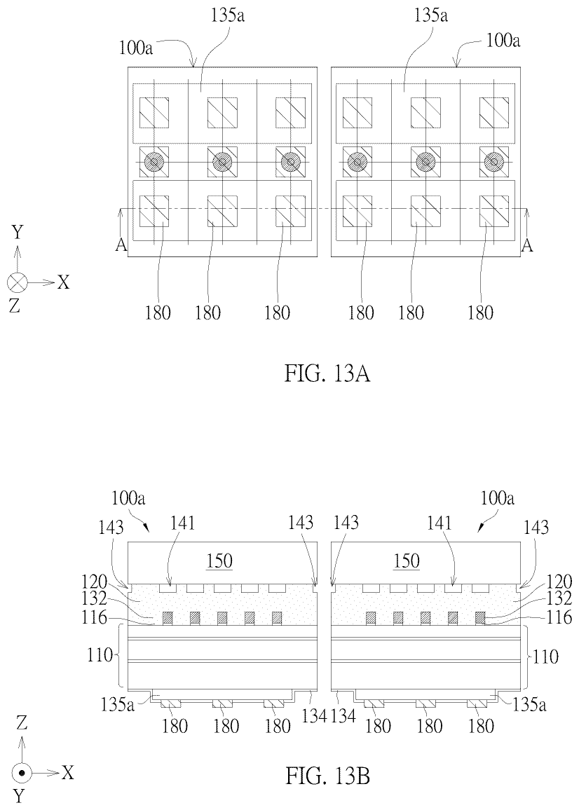

Referring to FIGS. 13A to 13B for a next step of the method of manufacturing the semiconductor device 100a. FIG. 13A is a bottom view of the semiconductor device 100a, and FIG. 12B is a sectional view along the section line A-A in FIG. 12A. In this step, a dicing process (such as mechanical cutting, split or laser cutting) is performed to the wafer 100W along the scribe lines SL to separate the base 150, the bonding structure 120, the semiconductor stack 110 and the insulating layer 134 between different chip regions, so as to form a plurality of the semiconductor devices 100a which are separated from each other.

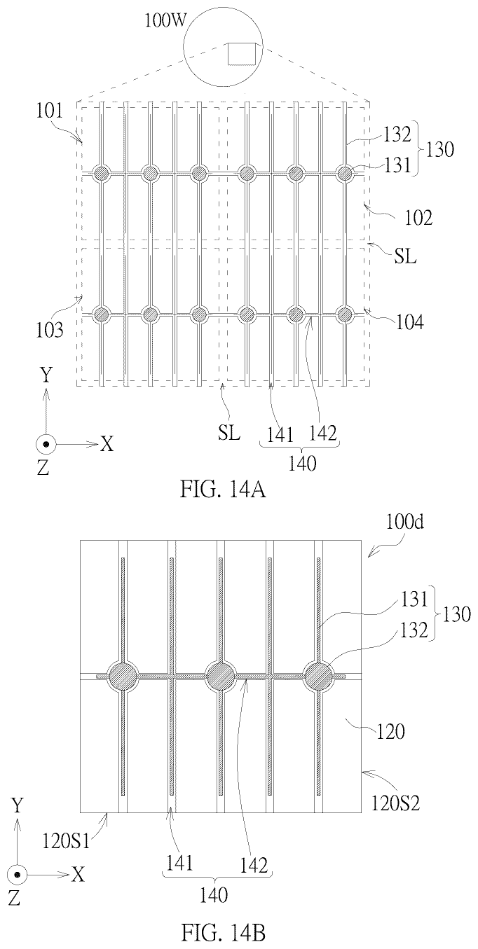

FIG. 14A is a schematic top view of a partial area of a wafer 100W before the dicing process according to one embodiment of the present disclosure, and FIG. 14B is a schematic top view of a semiconductor device 100d formed after dicing the wafer 100W of FIG. 14A. As shown in FIG. 14A, there are a first chip region 101, a second chip region 102, a third chip region 103, and a fourth chip region 104 defined on the wafer 100W and arranged in an array, and each chip region is surrounded by scribe lines SL. The scribe line SL may extend along the X-axis and/or the Y-axis.

In this embodiment, on the bonding structure 120, the first trench 141 and the second trench 142 are formed but the third trench 143 is not. As shown in FIG. 14A, the first trench 141 and the second trench 142 are interconnected, and the first trench 141 and/or the second trench 142 may extend across different chip regions and the scribe lines SL to the edge of the wafer 100W (not shown). Therefore, during bonding the base 150 to the bonding structure 120, the air remaining between the base 150 and the bonding structure 120 can be discharged to the outside of the wafer 100W through the first trench 141 and/or the second trench 142 to prevent formation of air bubbles at the bonding surface, so the production yield and quality of the semiconductor device 100d can be improved. After the dicing process, the first chip region 101, the second chip region 102, the third chip region 103, and the fourth chip region 104 all become the semiconductor devices 100d. The semiconductor device 100d has a similar structure to the aforementioned semiconductor device 100a, and the main difference therebetween is that the semiconductor device 100d does not have a third trench 143 extending along the first side surface 120S1 and/or the second side surface 120S2 of the bonding structure 120. As shown in FIG. 14B, for each of the semiconductor devices 100d, the first trench 141 extends toward the first side surface 120S1 to communicate with the outside, and the second trench 142 extends toward the second side surface 120S2 to communicate with the outside.

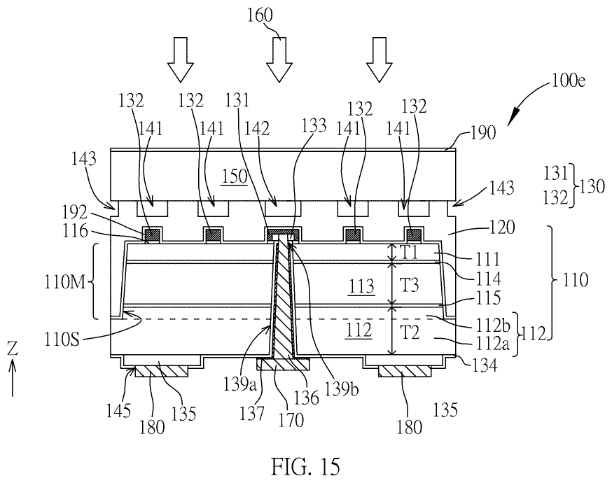

FIG. 15 is a schematic sectional view of a semiconductor device 100e according to one embodiment of the present disclosure. The semiconductor device 100e has a similar structure to the aforementioned semiconductor device 100a, and the main difference is that the semiconductor device 100e optionally includes an etching protection structure 137, and the semiconductor stack 110 of the semiconductor device 100e optionally includes a mesa structure 110M. Specifically, the semiconductor stack 110 can be patterned to remove the first semiconductor structure 111, the first tunneling structure 114, the third semiconductor structure 113, and the second tunneling structure 115 at the periphery and expose the second semiconductor structure 112, thereby forming the mesa structure 110M. As shown in FIG. 15, the second semiconductor structure 112 includes a first portion 112a and a second portion 112b, and the mesa structure 110M is located on the first portion 112a and includes the first semiconductor structure 111, the first tunneling structure 114, the third semiconductor structure 113, the second tunneling structure 115, and the second portion 112b. Furthermore, the first contact structure 116, the protecting layer 133 and the conductive structure 130 are all located on the mesa structure 110M. Furthermore, the mesa structure 110M is embedded in the bonding structure 120 so that a sidewall 110S of the mesa structure 110M and the exposed first portion 112a are covered and protected by the bonding structure 120. In this manner, the risk of damage to the sidewall 110S during the dicing process can be reduced, thereby improving the reliability of the semiconductor device 100e. In some embodiments, in the horizontal direction, the max width of the first portion 112a is larger than the max width of the second portion 112b, and the width of the first portion 112a is larger than the width of any structure of the mesa structure 110M. In some embodiments, in the horizontal direction, the max width of the second portion 112b can be larger than the max width of the first semiconductor structure 111 or the max width of the third semiconductor structure 113. In some embodiments, through adjustment of the patterning process, the sidewall 110S of the mesa structure 110M may have two or more inclination angles with respect to the surface of the second semiconductor structure 112. For example, the inclination angle of the sidewall of the second portion 112b may be different from the inclination angle of the sidewall of the first semiconductor structure 111 or the inclination angle of the sidewall of the third semiconductor structure 113 (not shown).

The etching protection structure 137 is disposed between the insulating layer 134 and the first electrode structure 170 and between the insulating layer 134 and the electrical connecting element 136 to protect the insulating layer 134 during forming the second through hole 139b. More specifically, the etching protection structure 137 is formed below the insulating layer 134 and extends into the first through hole 139a, and has an opening corresponding to the second through hole 139b. In some embodiments, the etching protection structure 137 covers or conformally covers the insulating layer 134 which is located below the second semiconductor structure 112 and within the first through hole 139a. The etching protection structure 137 includes a material different from that of the insulating layer 134. Compared to the insulating layer 134, the etching protection structure 137 has better corrosion resistance to the etching medium (such as plasma) applied to form the second through hole 139b. Therefore, the etching protection structure 137 can protect the insulating layer 134 located at the periphery and the inside of the first through hole 139a from being damaged by the etching medium, so as to reduce the risk of leakage between the semiconductor stack 110 and the first electrode structure 170.

As shown in FIG. 15, in the vertical direction, the etching protection structure 137 may completely overlap with the first electrode structure 170. In the horizontal direction, the etching protection structure 137 may has a width W5 equal to or smaller than the width of the first electrode structure 170. The etching protection structure 137 may be formed on the surface of the insulating layer 134 through a patterning process before forming the second through hole 139b. The etching protection structure 137 can include a single layer or multiple layers. The etching protection structure 137 may include metal or insulating material. The metal may include chromium (Cr), platinum (Pt) or titanium (Ti). The insulating material may include tantalum oxide (TaOx), aluminum oxide (AlOx), titanium oxide (TiOx), silicon nitride (SiNx) or titanium nitride (TiN). In some embodiments, the etching protection structure 137 has a thickness T8 in the vertical direction can be in a range of 50 nm to 200 nm.

As shown in FIG. 15, the semiconductor device 100e may optionally include a first anti-reflection layer 190 and/or a second anti-reflection layer 192. The first anti-reflection layer 190 is disposed on the surface of the base 150 away from the semiconductor stack 110 to reduce reflection of the incident light 160 on the base 150. The second anti-reflection layer 192 is disposed between the bonding structure 120 and the semiconductor stack 110 to reduce reflection of the incident light 160 on the semiconductor stack 110. More specifically, the second anti-reflection layer 192 covers the first semiconductor structure 111 and the conductive structure 130. When the semiconductor stack 110 includes the mesa structure 110M, the second anti-reflection layer 192 may further extends downward to cover the sidewall 110S and the first portion 112a of the second semiconductor structure 112 to improve the photoelectric conversion efficiency and provide more protection to the surface of the semiconductor stack 110. The first anti-reflection layer 190 and the second anti-reflection layer 192 may include a single layer or multiple layers, and may include insulating materials, such as tantalum oxide (TaOx), aluminum oxide (AlOx), silicon oxide (SiOx), titanium oxide (TiOx), silicon nitride (SiNx), silicon oxynitride (SiOxNy), niobium pentoxide (Nb₂O₅) or spin-on glass (SOG). The positions, relative relationships, material compositions, and other contents of other structures/layers/elements of the semiconductor device 100e have been described in detail in the previous embodiments and will not be repeated herein.

The semiconductor device of the present disclosure can be applied to products in various fields, such as communication, sensing, or power supply system, for example, can be used in a mobile phone, tablet, an automotive driver monitoring system (DMS), a television, computer, wearable device (such as watch, bracelet or earphone), outdoor display device, or power supply device.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a base;
a semiconductor stack comprising a first semiconductor structure and a second semiconductor structure, the first semiconductor structure located between the second semiconductor structure and the base;
a bonding structure disposed between the base and the first semiconductor structure;
a contact structure disposed between the bonding structure and the first semiconductor structure;
a conductive structure covering the contact structure; and
a first through hole penetrating the semiconductor stack and the contact structure to contact the conductive structure.

2. The semiconductor device according to claim 1, further comprising a protecting layer corresponding to the first through hole and disposed between the conductive structure and the contact structure.

3. The semiconductor device according to claim 2, wherein the conductive structure has a width larger than that of the protecting layer.

4. The semiconductor device according to claim 2, further comprising an electrical connecting element which is disposed in the first through hole and connects to the protecting layer.

5. The semiconductor device according to claim 4, wherein the electrical connecting element penetrates the protecting layer to connect to the conductive structure.

6. The semiconductor device according to claim 4, further comprising an insulating layer surrounding the electrical connecting element.

7. The semiconductor device according to claim 6, wherein the insulating layer connecting to the protecting layer.

8. The semiconductor device according to claim 2, wherein the protecting layer comprises an insulating material.

9. The semiconductor device according to claim 1, wherein the conductive structure has a width larger than that of the first through hole.

10. The semiconductor device according to claim 1, wherein the first semiconductor structure has a thickness smaller than that of the second semiconductor structure.

11. The semiconductor device according to claim 1, wherein the conductive structure comprises a connecting portion corresponding to the first through hole, and an extending portion extending from the connecting portion.

12. The semiconductor device according to claim 1, further comprising an electric connecting element disposed in the first hole to connect the conductive structure.

13. The semiconductor device according to claim 12, further comprising an insulating structure disposed between the electrical connecting element and the semiconductor stack.

14. The semiconductor device according to claim 13, further comprising an etching protection structure disposed between the insulating layer and the electrical connecting element.

15. The semiconductor device according to claim 12, further comprising a first electrode structure located below the second semiconductor structure and connected to the electrical connecting element.

16. The semiconductor device according to claim 15, further comprising a second electrode structure connected to the second semiconductor structure, wherein the second electrode structure is separated from the first electrode structure.

17. The semiconductor device according to claim 1, wherein the semiconductor stack further comprises a third semiconductor structure located between the first semiconductor structure and the second semiconductor structure; wherein the first semiconductor structure, the second semiconductor structure and the third semiconductor structure respectively have a first band gap, a second band gap and a third band gap, and the third band gap is smaller than the first band gap and larger than the second band gap.

18. The semiconductor device according to claim 1, further comprising an anti-reflection layer disposed between the bonding structure and the conductive structure, and wherein the anti-reflection layer covers the conductive structure and the first semiconductor structure.

19. The semiconductor device according to claim 1, wherein the second semiconductor structure has a first portion and a second portion connecting the first portion and the first semiconductor structure, and the first portion has a width larger than that of the second portion.

20. The semiconductor device according to claim 19, wherein the first portion has a width larger than that of the first semiconductor structure.
